(19) United States
(12) Patent Application Publication
(10) Pub. No.: US 2015/0226783 A1
(43) Pub. Date: Aug. 13, 2015

(54) PROBE CARD AND WAFER TEST SYSTEM INCLUDING THE SAME

(71) Applicant: SAMSUNG ELECTRONICS CO., LTD., Suwon-si (KR)

(72) Inventor: SANG-GU KANG, Hwaseong-si (KR)

(21) Appl. No.: 14/598,688

(22) Filed: Jan. 16, 2015

(30) Foreign Application Priority Data
Feb. 11, 2014 (KR) 10-2014-0015647

(51) Int. Cl. G01R 31/26; G01R 1/073

(52) U.S. Cl. CPC G01R 31/26; G01R 1/073

(57) ABSTRACT

A wafer test system includes a probe card and a test controller. The probe card is connected to at least one device under test (DUT) disposed on a wafer, and is configured to limit a current flowing into the at least one DUT to be about equal to or less than a threshold current. The test controller is configured to control an amplitude of the threshold current.

### CROSS-REFERENCE TO RELATED APPLICATION

This application claims priority under 35 U.S.C. §119 to Korean Patent Application No. 10-2014-0015647 filed on Feb. 11, 2014, the disclosure of which is incorporated by reference herein in its entirety.

### TECHNICAL FIELD

Exemplary embodiments of the inventive concept relate to a probe card and a wafer test system including the same, and more particularly, to a probe card for testing a plurality of devices under test (DUTs) included in a wafer, and a wafer test system including the probe card.

### DISCUSSION OF THE RELATED ART

When testing integrated circuit (IC) on wafers, it is cost-efficient to reduce a test time per wafer by testing as many devices as possible in parallel. Test system controllers have been developed to increase the number of channels to increase the number of devices that may be tested in parallel. Probe cards, which function as an interface between the test system controllers and the wafers, typically have a shorter life span than the test system controllers due to, for example, abrasion of probes on the probe cards. Accordingly, the probe cards may be replaced at a faster rate than the test system controllers.

Although the test system controllers may perform fault testing in parallel, when there is a damaged or deteriorated probe in a probe card that is connected to a device under test (DUT), a wafer test performed on that DUT may not be performed as accurately and efficiently as a wafer test performed on other DUTs that are not connected to the damaged or deteriorated probe.

### SUMMARY

Exemplary embodiments of the inventive concept provide a probe card for testing a plurality of devices under test (DUTs) which may prevent abnormal operations due to overcurrent, and a wafer test system including the probe card.

According to an exemplary embodiment of the inventive concept, a wafer test system includes a probe card that is connected to at least one device under test (DUT) and limits a current flowing into the at least one DUT to be about equal to or less than a threshold current, and a test controller that controls an amplitude of the threshold current.

The probe card may include at least one current limitation switch that is connected to the at least one DUT.

The probe card may include at least one resistor that is connected to the at least one current limitation switch, and the test controller may control the amplitude of the threshold current by adjusting the resistance value of the resistor.

The probe card may include at least one passive device or at least one active device connected to the at least one current limitation switch, and the test controller may control the amplitude of the threshold current by adjusting a voltage or a current flowing in the at least one passive device or active device.

The current limitation switches may be operated using an external power source.

When the threshold current flows in a DUT that is connected to the current limitation switch for a certain amount of time, the current limitation switch may block the current that flows into the DUT.

When a current greater than the threshold current flows in a DUT that is connected to the current limitation switch, the current limitation switch may limit current that flows into the DUT to be about equal to or less than the threshold current.

The at least one current limitation switch may block the current flowing into the at least one DUT in response to the current flowing into the at least one DUT being greater than the threshold current for a predetermined amount of time.

The at least one current limitation switch may reduce the current flowing into the at least one DUT to be about equal to or less than the threshold current in response to the current flowing into the at least one DUT being greater than the threshold current.

The amplitude of the threshold current may vary according to a DUT that corresponds to the threshold current.

The amplitude of the threshold current may be adjusted by the test controller before testing a DUT.

The amplitude of the threshold current may be changed while testing a DUT.

According to an exemplary embodiment of the inventive concept, a probe card includes a current limitation switch controlling an amplitude of a current that flows into at least one DUT, and a current limitation device controlling an amplitude of a threshold current that is connected to and limited by the current limitation switch.

The current limitation switch may be operated using an external power source.

When the threshold current flows in a DUT that is connected to the current limitation switch for a certain amount of time, the current limitation switch may block current that flows into the DUT.

When a current greater than the threshold current flows in a DUT that is connected to the current limitation switch, the current limitation switch may limit the current that flows into the DUT to be about equal to or less than the threshold current.

The amplitude of the threshold current may be adjusted by a test controller while testing a DUT.

According to an exemplary embodiment of the inventive concept, a probe card includes a current limitation witch and a current limitation device. The current limitation switch is configured to control an amplitude of a current flowing into at least one DUT. The current limitation device is configured to control an amplitude of a threshold current. The current flowing into the at least one DUT flows through the current limitation device, the current limitation device is connected to the current limitation switch, and the current flowing through the current limitation device and into the at least one DUT is limited by the current limitation switch.

According to an exemplary embodiment of the inventive concept, a wafer test system includes a probe card and a test controller. The probe card is connected to a plurality of DUTs disposed on a wafer, and is configured to limit a current flowing into each of the plurality of DUTs to be about equal to or less than a corresponding threshold current from among a plurality of threshold currents. The test controller is configured to control an amplitude of each of the plurality of threshold currents.

### BRIEF DESCRIPTION OF THE DRAWINGS

The above and other features of the inventive concept will become more apparent by describing in detail exemplary embodiments thereof with reference to the accompanying drawings, in which:

FIG. 1 is a block diagram of a wafer test system including a probe card according to an exemplary embodiment of the inventive concept.

FIG. 2 is a flowchart illustrating operations of a wafer test system according to an exemplary embodiment of the inventive concept.

FIG. 3 is a block diagram of a wafer test system including a probe card according to an exemplary embodiment of the inventive concept.

FIG. 4 is a block diagram of a wafer test system including a probe card according to an exemplary embodiment of the inventive concept.

FIG. 5 is a block diagram of a wafer test system including a probe card according to an exemplary embodiment of the inventive concept.

FIG. 6 is a block diagram of a wafer test system including a probe card according to an exemplary embodiment of the inventive concept.

FIG. 7 is a block diagram of a wafer test system including a probe card according to an exemplary embodiment of the inventive concept.

FIG. 8 is a block diagram of a wafer test system including a probe card according to an exemplary embodiment of the inventive concept.

FIG. 9 is a flowchart illustrating operations of a wafer test system according to an exemplary embodiment of the inventive concept.

FIG. 10 is a schematic perspective view of a test system according to an exemplary embodiment of the inventive concept.

### DETAILED DESCRIPTION OF THE EXEMPLARY EMBODIMENTS

Exemplary embodiments of the present inventive concept will be described more fully hereinafter with reference to the accompanying drawings. Like reference numerals may refer to like elements throughout the accompanying drawings. In the drawings, sizes of components may be exaggerated for clarity.

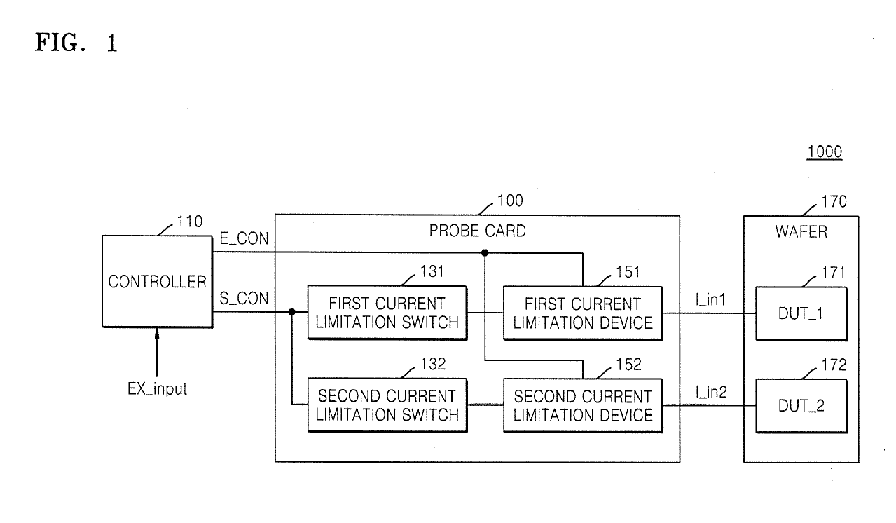

FIG. 1 is a block diagram of a wafer test system 1000 including a probe card 100 according to an exemplary embodiment of the inventive concept.

Referring to FIG. 1, the wafer test system 1000 may include the probe card 100 and a controller 110 (e.g., a test controller 110). The wafer test system 1000 may perform a fault test on a wafer 170. For example, the wafer test system 1000 may perform a fault test on a first device under test (hereinafter referred to as DUT_1) 171 and a second device under test (hereinafter referred to as DUT_2) 172 included in the wafer 170.

Although FIG. 1 illustrates two DUTs for convenience of description, it is to be understood that the number of DUTs is not limited thereto. For example, the number of DUTs may vary according to exemplary embodiments (e.g., the number of DUTs may be the same as the number of devices included in a wafer and may be, for example, a single DUT or a plurality of DUTs). Similarly, the number of other elements described herein (e.g., the number of current limitation switches, current limitation devices, resistors, active devices, passive devices, etc.) is not limited to the number of elements illustrated and described herein (e.g., exemplary embodiments may include a single one of each of these elements or a plurality of each of these elements).

The controller 110 may control the probe card 100 such that a fault test is performed on the DUT_1 171 and the DUT_2 172. To control the probe card 100, the controller 110 may generate a device control signal E_CON and a switch control signal S_CON. The device control signal E_CON and the switch control signal S_CON may be input to the probe card 100 via, for example, two input terminals.

The switch control signal S_CON generated by the controller 110 may control a first current limitation switch 131 and a second current limitation switch 132. For example, when currents I_in1 and I_in2 are greater than threshold currents I_th1 and I_th2, which are applied to the DUT_1 171 and the DUT_2 172, respectively, the controller 110 may turn the first and second current limitation switches 131 and 132 off using the switch control signal S_CON. In an exemplary embodiment, the controller 110 may monitor the amplitudes of currents and I_in2 that flow into the DUT_1 171 and the DUT_2 172, and turn the first and second current limitation switches 131 and 132 on and off using the switch control signal S_CON.

The device control signal E_CON generated by the controller 110 may control a first current limitation device 151 and a second current limitation device 152. For example, the device control signal E_CON may adjust the threshold currents I_th1 and I_th2 corresponding to the currents I_in1 and I_in2 that flow into the DUT_1 171 and the DUT_2 172 by adjusting respective resistance values of the first and second current limitation devices 151 and 152. The first and second current limitation devices 151 and 152 are connected to and limited by the first and second current limitation switches 131 and 132 (e.g., the current flowing through and output by the first and second current limitation devices 151 and 152 may be limited by the first and second current limitation switches 131 and 132). The first and second current limitation devices 151 and 152 may be, for example, passive devices (e.g., resistors) or active devices (e.g., transistors).

The controller 110 may generate the device control signal E_CON and the switch control signal S_CON using, for example, an external input signal EX_input that is received from a source external to the wafer test system 1000.

In an exemplary embodiment, the probe card 100 includes the first and second current limitation switches 131 and 132 and the first and second current limitation devices 151 and 152. The first and second current limitation devices 151 and 152 may control the threshold currents I_th1 and I_th2 of the DUT_1 171 and the DUT_2 172. When a current greater than the threshold currents I_th1 and I_th2 is flowing into the DUT_1 171 and the DUT_2 172, the first and second current limitation switches 131 and 132 may block or reduce the current flowing into the DUT_1 171 and the DUT_2 172. The first and second current limitation switches 131 and 132 are connected to the DUT_1 171 and the DUT_2 172, for example, via the first and second current limitation devices 151 and 152. The current flowing into the DUT_1 171 and the DUT_2 172 flows through the first and second current limitation devices 151 and 152 and into the DUT_1 171 and the DUT_2 172.

In a comparative example, when the first and second current limitation switches 131 and 132 are not provided, a signal connected to the DUT_1 171 may be shorted due to deterioration of the DUT_1 171 in the wafer 170. Due to the short, an overcurrent or inrush current may flow in a probe that corresponds to the DUT_1 171. In this case, since current is uniformly transmitted from the probe card 100 to the wafer 170, the current I_in2 that flows into the DUT_2 172 may be significantly reduced, and thus, a fault test may not be performed on the DUT_2 172.

The controller 110 according to an exemplary embodiment of the inventive concept may control the first and second current limitation devices 151 and 152 that respectively correspond to the DUT_1 171 and the DUT_2 172, and may control the respective amplitudes of the threshold currents I_th1 and I_th2 of the DUT_1 171 and the DUT_2 172. The amplitude of the threshold currents I_th1 and I_th2 may respectively vary according to the DUT_1 171 and the DUT_2 172. The controller 110 may adjust the amplitude of the threshold currents I_th1 and I_th2 before the DUT_1 171 and the DUT_2 172 are tested or while the DUT_1 171 and the DUT_2 172 are being tested. The controller 110 may control the first and second current limitation devices 151 and 152 such that a current greater than a threshold current may not flow through the first and second current limitation switches 131 and 132. As a result, overcurrent or inrush current may be prevented from flowing into a DUT. Therefore, in the wafer test system 1000 according to an exemplary embodiment of the inventive concept, a fault test may be performed on the DUT_2 172 even when the DUT_1 171 is deteriorated, or vice versa.

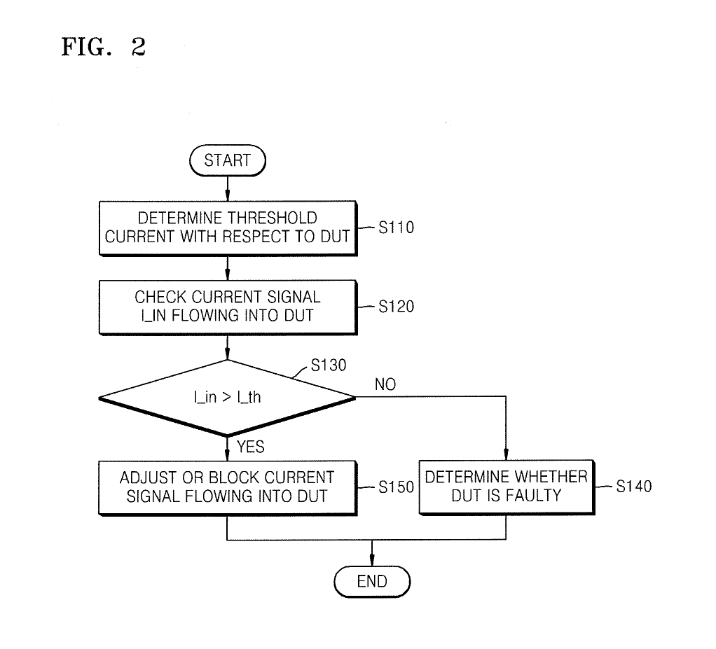

FIG. 2 is a flowchart illustrating operations of a wafer test system according to an exemplary embodiment of the inventive concept.

Although FIG. 2 is described with reference to the wafer test system 1000 of FIG. 1, it is to be understood that the operations of FIG. 2 may also refer to other wafer test systems according to exemplary embodiments of the inventive concept described herein.

Referring to FIG. 2, the wafer test system 1000 determines threshold current signals I_th1 and I_th2 with respect to the DUT_1 171 and the DUT_2 172 at operation S110. The wafer test system 1000 checks current signals I_in1 and I_in2 that flow into the DUT_1 171 and the DUT_2 172 at operation S120. At operation S130, it is determined whether the current signals I_in1 and I_in2 are greater than the threshold current signals I_th1 and I_th2. When the current signals I_in1 and I_in2 are greater than the threshold current signals I_th1 and I_th2, the wafer test system 1000 adjusts or blocks the current signals I_in1 and I_in2 that flow into the DUT_1 171 and the DUT_2 172 at operation S150. When the current signals I_in1 and I_in2 are less than the threshold current signals I_th1 and I_th2, the wafer test system 1000 determines whether the DUT_1 171 and the DUT_2 172 are faulty at operation S140.

For example, when the current signal I_in1 is greater than the threshold current signal I_th1, the controller 110 may limit the current signal I_in1 that flows into the DUT_1 171 such that the current signal I_in1 is about equal to or less than the threshold current signal I_th1. Similarly, when the current signal I_in2 is greater than the threshold current signal I_th2, the controller 110 may limit the current signal I_in2 that flows into the DUT_2 172 such that the current signal I_in2 is about equal to or less than the threshold current signal I_th2. Herein, when one value is described as being about equal to another value (e.g., “a current signal is about equal to a threshold current signal”), it is to be understood that the values are equal to each other within a measurement error, or if measurably unequal, are close enough in value to be functionally equal to each other as would be understood by a person having ordinary skill in the art.

In another example, the controller 110 may adjust a threshold current related to the DUT_1 171 and a threshold current related to the DUT_2 172 such that the respective amplitudes of the threshold currents are different from each other.

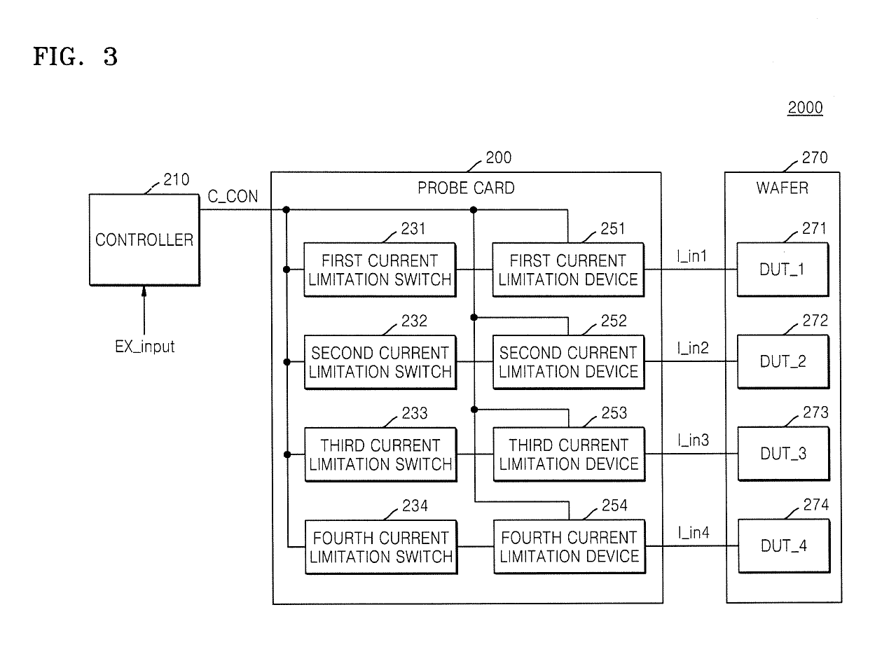

FIG. 3 is a block diagram of a wafer test system 2000 including a probe card 200 according to an exemplary embodiment of the inventive concept.

Referring to FIG. 3, the wafer test system 2000 may include the probe card 200 and a controller 210. The wafer test system 2000 may perform a fault test on a wafer 270. Although FIG. 3 illustrates four DUTs for convenience of description, it is to be understood that the number of DUTs is not limited thereto. For example, the number of DUTs may vary according to exemplary embodiments (e.g., the number of DUTs may be the same as the number of devices included in a wafer).

The controller 210 may control the probe card 200 such that the fault test is performed on DUT_1 271 to DUT_4 274. To control the probe card 200, the controller 210 may generate a card control signal C_CON.

The card control signal C_CON generated by the controller 210 may be input to the probe card 200 via, for example, a single input terminal. The card control signal C_CON may include the device control signal E_CON and the switch control signal S_CON, which are described with reference to FIG. 1.

The card control signal C_CON may control first to fourth current limitation switches 231 to 234 and first to fourth current limitation devices 251 to 254. The controller 210 may generate the card control signal C_CON using, for example, the external input signal EX_input that is received from a source external to the wafer system 2000.

In an exemplary embodiment, the probe card 200 includes the first to fourth current limitation switches 231 to 234 and the first to fourth current limitation devices 251 to 254. The first to fourth current limitation devices 251 to 254 may control threshold currents I_th1 to I_th4 of the DUT_1 271 to DUT_4 274. When a current greater than the threshold currents I_th1 to f_th4 is flowing into the DUT_1 271 to DUT_4 274, the first to fourth current limitation switches 231 to 234 may block or reduce the current flowing into the DUT_1 271 to DUT_4 274.

By using the card control signal C_CON that uses a single input terminal, the probe card 200 according to an exemplary embodiment of the inventive concept may control each of the first to fourth current limitation devices 251 to 254 to control the respective amplitudes of the threshold currents I_th1 to I_th4 of the DUT_1 271 to DUT_4 274.

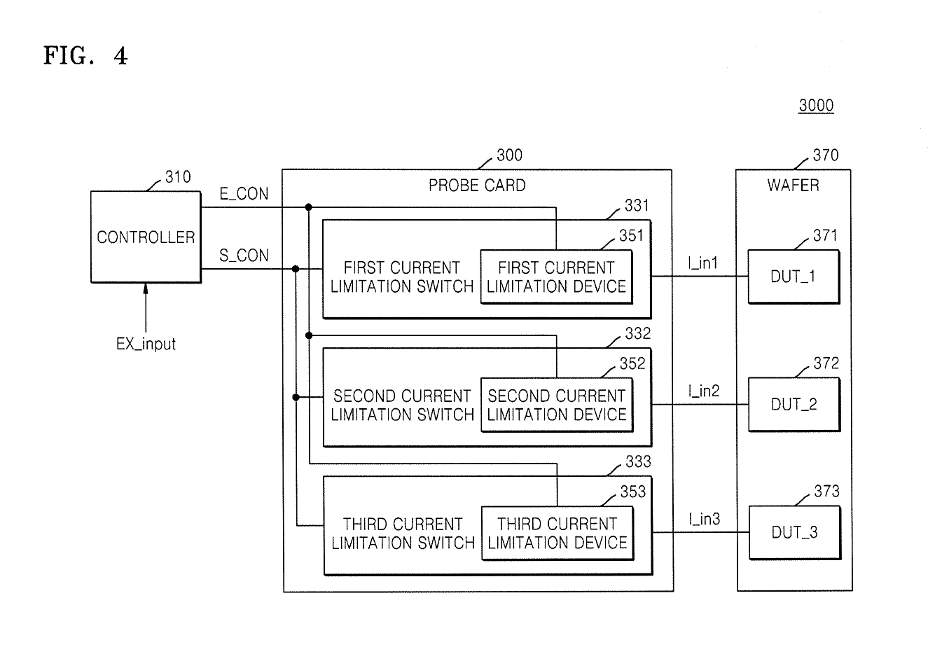

FIG. 4 is a block diagram of a wafer test system 3000 including a probe card 300 according to an exemplary embodiment of the inventive concept.

Referring to FIG. 4, the wafer test system 3000 may include the probe card 300 and a controller 310. The wafer test system 3000 may perform a fault test on a wafer 370. Although FIG. 4 illustrates three DUTs (e.g., DUT_1 371 to DUT_3 373) for convenience of description, it is to be understood that the number of DUTs is not limited thereto. For example, the number of DUTs may vary according to exemplary embodiments (e.g., the number of DUTs may be the same as the number of devices included in a wafer). Further, for convenience of description, further description of operations and elements of FIG. 4 that are similar to operations and elements of FIGS. 1-3 that have been previously described may be omitted herein.

The probe card 300 may include first to third current limitation switches 331 to 333. The first to third current limitation switches 331 to 333 may respectively include first to third current limitation devices 351 to 353. For example, elements included in the first to third current limitation switches 331 to 333 may be used by the first to third current limitation devices 351 to 353.

According to exemplary embodiments, at least one passive device or at least one active device may be connected to the current limitation switches 331 to 333. Therefore, configurations of the probe card 300 according to the exemplary embodiment shown in FIG. 4 may be simplified by using the same passive devices (e.g., resistors) or active devices (e.g., transistors) included in the first to third current limitation switches 331 to 333 to implement the first to third current limitation devices 351 to 353. The amplitude of the threshold currents may be controlled by adjusting a voltage or a current flowing in the passive device(s) or the active device(s).

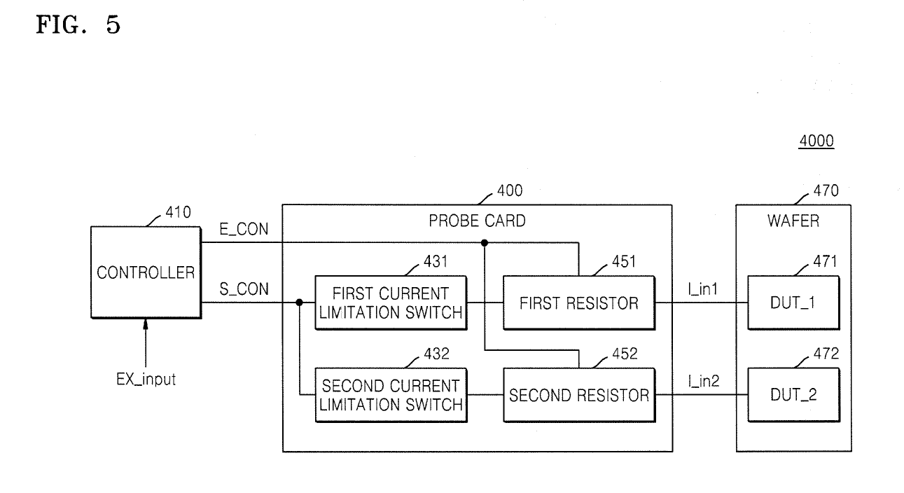

FIG. 5 is a block diagram of a wafer test system 4000 including a probe card 400 according to an exemplary embodiment of the inventive concept.

Referring to FIG. 5, the wafer test system 4000 may include the probe card 400 and a controller 410. Although FIG. 5 illustrates two DUTs for convenience of description, it is to be understood that the number of DUTs is not limited thereto. For example, the number of DUTs may vary according to exemplary embodiments (e.g., the number of DUTs may be the same as the number of devices included in a wafer). Further, for convenience of description, further description of operations and elements of FIG. 5 that are similar to operations and elements of FIGS. 1-4 that have been previously described may be omitted herein.

The probe card 400 may include first and second current limitation switches 431 and 432, and first and second resistors 451 and 452 that function as current limitation devices. The first and second resistors 451 and 452 may control threshold currents I_th1 and I_th2 of the DUT_1 471 and the DUT_2 472 of the wafer 470. For example, the amplitude of the threshold currents I_th1 and I_th2 may be controlled by adjusting the resistance values of the first and second resistors 451 and 452. When a current greater than the threshold currents I_th1 and I_th2 is flowing into the DUT_1 471 and the DUT_2 472, the first and second resistors 451 and 452 may block or reduce the current flowing into the DUT_1 471 and the DUT_2 472. Although FIG. 5 illustrates the inclusion of resistors in the probe card 400, the probe card 400 is not limited thereto. For example, the probe card 400 may include an active device(s) that includes at least one of, for example, a capacitor, an inductor, and a resistor.

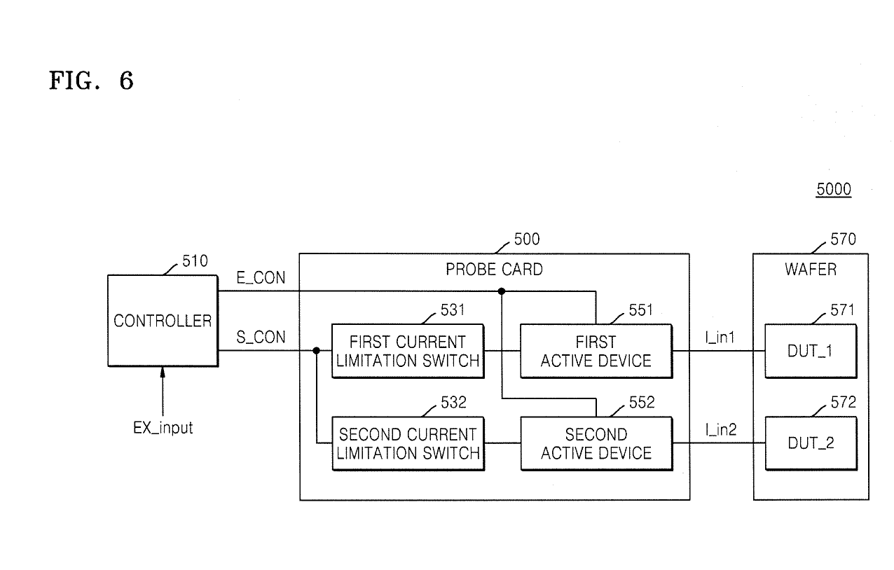

FIG. 6 is a block diagram of a wafer test system 5000 including a probe card 500 according to an exemplary embodiment of the inventive concept.

Referring to FIG. 6, the wafer test system 5000 may include the probe card 500 and a controller 510. Although FIG. 6 illustrates two DUTs for convenience of description, it is to be understood that the number of DUTs is not limited thereto. For example, the number of DUTs may vary according to exemplary embodiments (e.g., the number of DUTs may be the same as the number of devices included in a wafer). Further, for convenience of description, further description of operations and elements of FIG. 6 that are similar to operations and elements of FIGS. 1-5 that have been previously described may be omitted herein.

The probe card 500 may include first and second current limitation switches 531 and 532, and first and second active devices 551 and 552 that function as current limitation devices. The first and second active devices 551 and 552 may control threshold currents I_th1 and I_th2 of DUT_1 571 and the DUT_2 572 of the wafer 570. When a current greater than the threshold currents I_th1 and I_th2 is flowing into the DUT_1 571 and the DUT_2 572, the first and second active devices 551 and 552 may block or reduce the current flowing into the DUT_1 571 and the DUT_2 572.

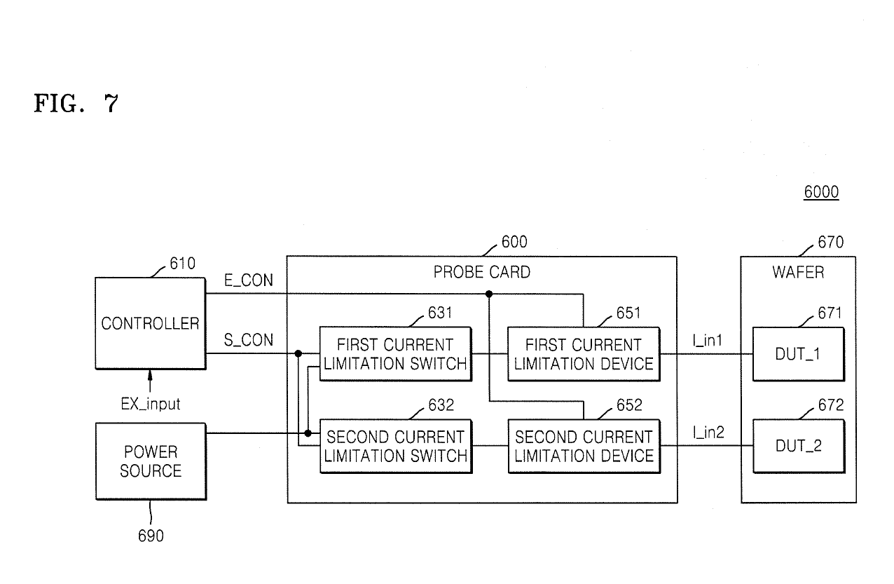

FIG. 7 is a block diagram of a wafer test system 6000 including a probe card 600 according to an exemplary embodiment of the inventive concept.

Referring to FIG. 7, the wafer test system 6000 may include the probe card 600, a power source 690, and a controller 610. The wafer test system 6000 may perform a fault test on a wafer 670. For example, the wafer test system 6000 may perform a fault test on a DUT_1 671 and a DUT_2 672 included in the wafer 670. Although FIG. 7 illustrates two DUTs for convenience of description, it is to be understood that the number of DUTs is not limited thereto. For example, the number of DUTs may vary according to exemplary embodiments (e.g., the number of DUTs may be the same as the number of devices included in a wafer). Further, for convenience of description, further description of operations and elements of FIG. 7 that are similar to operations and elements of FIGS. 1-6 that have been previously described may be omitted herein.

The power source 690 may supply power for driving first and second current limitation switches 631 and 632 and/or first and second current limitation devices 651 and 652.

The probe card 600 may include the first and second current limitation switches 631 and 632 and the first and second current limitation devices 651 and 652 that receive power from the external power source 690. Therefore, in an exemplary embodiment, power input from the controller 610 is not used to drive the first and second current limitation switches 631 and 632 and/or the first and second current limitation devices 651 and 652 (e.g., the first and second current limitation switches 631 and 632 and/or the first and second current limitation devices 651 and 652 may be operated using an external power source). As a result, in an exemplary embodiment, the wafer 670 may be tested using only a small amount of power without changing the design and functionality of the controller 610.

Similar to the exemplary embodiment shown in FIG. 1, the first and second current limitation devices 651 and 652 may control the threshold currents I_th1 and I_th2 of the DUT_1 671 and the DUT_2 672. When a current greater than the threshold currents I_th1 and I_th2 is flowing into the DUT_1 671 and the DUT_2 672, the first and second current limitation switches 631 and 632 may block or reduce the current flowing into the DUT_1 671 and the DUT_2 672.

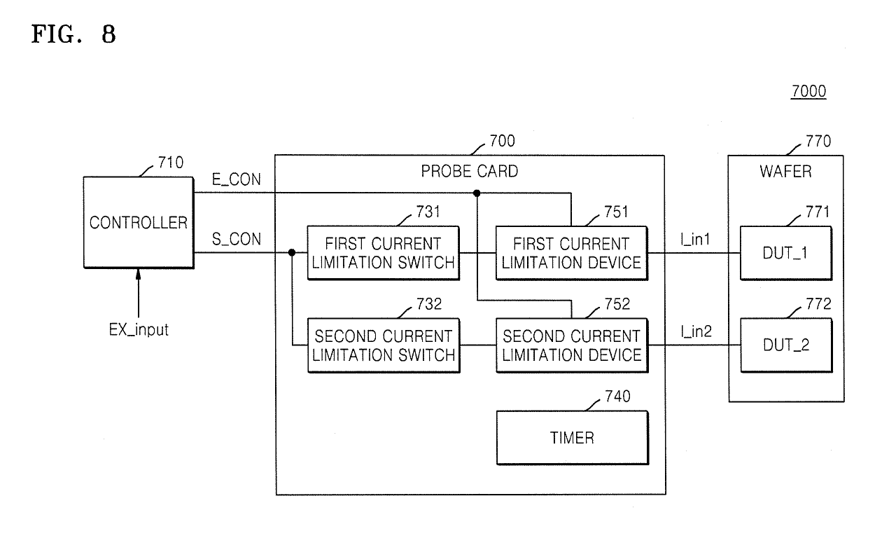

FIG. 8 is a block diagram of a wafer test system 7000 including a probe card 700 according to an exemplary embodiment of the inventive concept.

Referring to FIG. 8, the wafer test system 7000 may include the probe card 700 and a controller 710. The wafer test system 7000 may perform a fault test on a wafer 770. For example, the wafer test system 7000 may perform a fault test on a DUT_1 771 and a DUT_2 772 included in the wafer 770. Although FIG. 8 illustrates two DUTs for convenience of description, it is to be understood that the number of DUTs is not limited thereto. For example, the number of DUTs may vary according to exemplary embodiments (e.g., the number of DUTs may be the same as the number of devices included in a wafer). Further, for convenience of description, further description of operations and elements of FIG. 8 that are similar to operations and elements of FIGS. 1-7 that have been previously described may be omitted herein.

The controller 710 may control the probe card 700 such that a fault test is performed on the DUT_1 771 and the DUT_2 772. To control the probe card 700, the controller 710 may generate the device control signal E_CON and the switch control signal S_CON.

The switch control signal S_CON generated by the controller 710 may control a first current limitation switch 731 and a second current limitation switch 732. The device control signal E_CON generated by the controller 710 may control a first current limitation device 751 and a second current limitation device 752. The controller 710 may generate the device control signal E_CON and the switch control signal S_CON using the external input signal EX_input that is received from a source external to the wafer test system 7000.

The probe card 700 may include the first and second current limitation switches 731 and 732 and the first and second current limitation devices 751 and 752. The first and second current limitation devices 751 and 752 may control threshold currents I_th1 and I_th2 of the DUT_1 771 and the DUT_2 772.

The probe card 700 may further include a timer 740. When a current greater than the threshold currents I_th1 and I_th2 is flowing into the DUT_1 771 and the DUT_2 772, the first and second current limitation switches 731 and 732 may block or reduce the current flowing into the DUT_1 771 and the DUT_2 772 after a certain amount time has passed (e.g., after a predetermined amount of time has elapsed). For example, according to exemplary embodiments, the first and second current limitation switches 731 and 732 may block or reduce the current flowing into the DUT_1 771 and the DUT_2 772 in response to the flowing current being greater than the corresponding threshold current for a predetermined amount of time. When reducing the flowing current, the current may be reduced such that the amount of current is limited to be about equal to or less than the corresponding threshold current. In exemplary embodiments, the first and second current limitation switches 731 and 732 may block or reduce the current flowing into the DUT_1 771 and the DUT_2 772 without waiting for a predetermined amount of time to elapse.

In an exemplary embodiment, the controller 710 may control the first and second current limitation devices 751 and 752, which respectively correspond to the DUT_1 771 and the DUT_2 772, to control the respective amplitudes of the threshold currents I_th1 and I_th2 of the DUT_1 771 and the DUT_2 772. Using the timer 740, when a current greater than a threshold current is flowing via the first and second current limitation switches 731 and 732, the controller 710 may block or adjust the current flowing into the DUT_1 771 and the DUT_2 772 after a certain amount of time has passed (e.g., after a predetermined amount of time has elapsed). As a result, an overcurrent or an inrush current may be prevented from flowing into a DUT of the wafer 770. Therefore, in the wafer test system 7000 according to an exemplary embodiment, a fault test may be performed on the DUT_2 772 even when the DUT_1 771 is deteriorated, or vice versa.

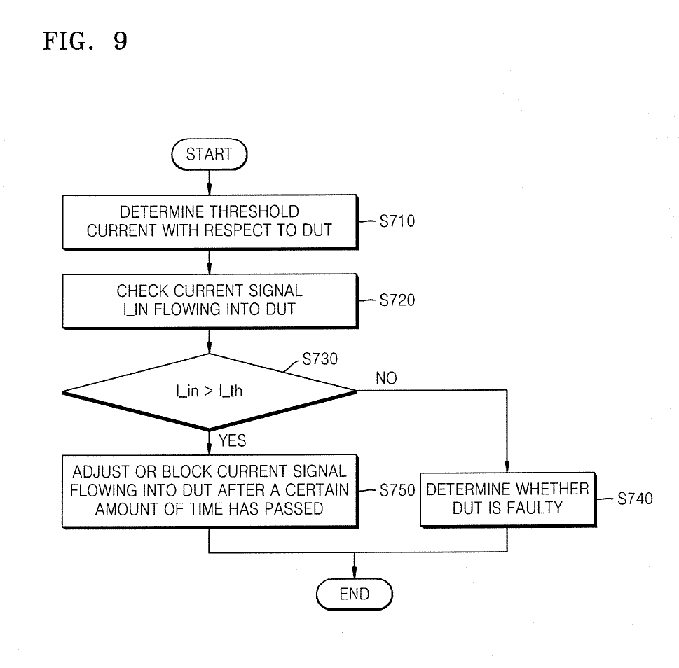

FIG. 9 is a flowchart illustrating operations of a wafer test system according to an exemplary embodiment of the inventive concept.

Although FIG. 9 is described with reference to the wafer test system 7000 of FIG. 8, it is to be understood that the operations of FIG. 9 may also refer to other wafer test systems according to exemplary embodiments of the inventive concept described herein.

Referring to FIG. 9, the wafer test system 7000 determines threshold current signals I_th1 and I_th2 with respect to the DUT_1 771 and the DUT_2 772 at operation S710. The wafer test system 7000 checks current signals and I_in2 that flow into the DUT_1 771 and the DUT_2 772 at operation S720. At operation S730, it is determined whether the current signals I_in1 and I_in2 are greater than the threshold current signals I_th1 and I_th2. When the current signals I_in1 and I_in2 are greater than the threshold current signals I_th1 and I_th2, the wafer test system 7000 adjusts or blocks the current signals I_in1 and I_in2 that flow into the DUT_1 771 and the DUT_2 772 after a certain amount of time has passed (e.g., after a predetermined amount of time has elapsed) at operation S750. When the current signals I_in1 and I_in2 are less than the threshold current signals I_th1 and I_th2, the wafer test system 7000 determines whether the DUT_1 771 and the DUT_2 772 are faulty at operation S740.

For example, when the current signal I_in1 is greater than the threshold current signal I_th1, the controller 710 may limit the current signal I_in1 that flows into the DUT_1 771 such that the current signal I_in1 is about equal to or less than the threshold current signal I_th1 after a certain amount of time has passed. Similarly, when the current signal I_in2 is greater than the threshold current signal I_th2, the controller 710 may limit the current signal I_in2 that flows into the DUT_2 772 such that the current signal I_in2 is about equal to or less than the threshold current signal I_th2 after a certain amount of time has passed.

In another example, the controller 710 may adjust a threshold current related to the DUT_1 771 and a threshold current related to the DUT_2 772 such that the respective amplitudes of the threshold currents are different from each other.

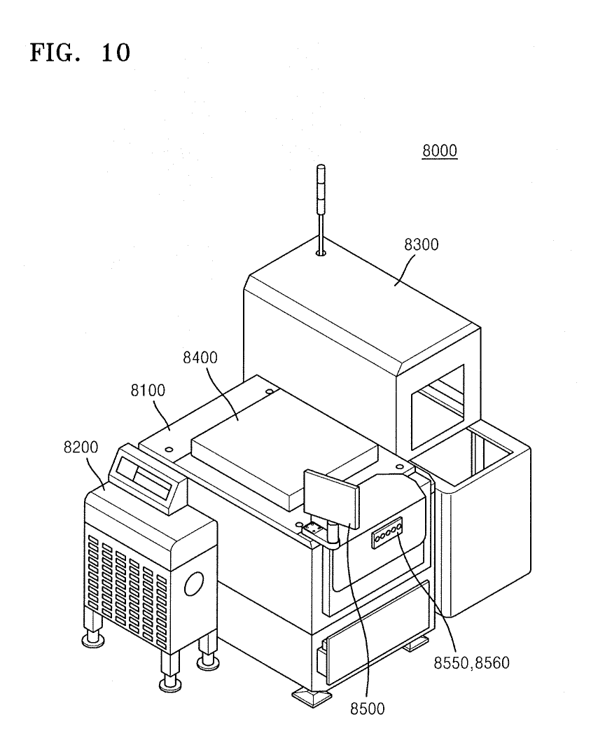

FIG. 10 is a schematic perspective view of a test system 8000 according to an exemplary embodiment of the inventive concept. Referring to FIG. 10, a test system 8000 according to an exemplary embodiment of the inventive concept may include a main body 8100, a laser beam provider 8200, and a wafer transfer module 8300. The test system 8000 may further include a test module 8400 and a monitor 8500 disposed, for example, on an upper portion of the main body 8100.

The laser beam provider 8200 may be provided, for example, at a side of the main body 8100, and may generate and provide a laser beam to the main body 8100. As shown in FIG. 10, the laser beam provider 8200 may be external to the main body 8100, however, exemplary embodiments are not limited thereto. In an exemplary embodiment in which the laser beam provider 8200 is disposed external to the main body 8100, the laser beam provider 8200 may be inspected, maintained, and replaced without affecting the main body 8100. The laser beam provider 8200 may be inspected and maintained more frequently than the main body 8100 as the result of a heat-emitting lamp being included in the laser beam provider 8200. Accordingly, disposing the laser beam provider 8200 external to the main body 8100 allows for these inspection and maintenance operations to be conveniently and efficiently performed.

The wafer transfer module 8300 may be disposed at another side of the main body 8100 and may provide a wafer to the main body 8100. For example, in an exemplary embodiment, the laser beam provider 8200 and the wafer transfer module 8300 may be disposed at opposite sides of the main body 8100 to efficiently use the space of the test system 8000, reduce movement of the wafer and a user, and increase efficiency of testing processes and equipment maintenance.

The test module 8400 may provide a circuit environment for testing the wafer loaded in the main body 8100. The monitor 8500 may display image information and map information of the probe card 100 of FIG. 1 for testing the wafer.

A control part 8550 may be provided in the main body 8100. The control part 8550 may order and control operations of the test system 8000. Functions and operations of the control part 8550 may include, for example, those of the controllers 110, 210, 310, 410, and 510 that are described with reference to FIGS. 1 to 7. A control panel 8560, which may communicate with the control part 8550, may be provided, for example, in an outer front portion of the main body 8100. The control panel 8560 may include various control buttons for operating the test system 8000. For example, the user may manipulate elements of the control panel 8560 to operate, complete, or transmit commands to the controller 8550.

While the inventive concept has been particularly shown and described with reference to the exemplary embodiments thereof, it will be understood by those of ordinary skill in the art that various changes in form and detail may be made therein without departing from the spirit and scope of the inventive concept as defined by the following claims.

What is claimed is:

1. A wafer test system, comprising:
a probe card connected to at least one device under test (DUT) disposed on a wafer, wherein the probe card is configured to limit a current flowing into the at least one DUT to be about equal to or less than a threshold current; and
a test controller configured to control an amplitude of the threshold current.

2. The wafer test system of claim 1, wherein the probe card comprises at least one current limitation switch connected to the at least one DUT.

3. The wafer test system of claim 2, wherein the probe card further comprises at least one resistor connected to the at least one current limitation switch, wherein the test controller is configured to control the amplitude of the threshold current by adjusting a resistance value of the at least one resistor.

4. The wafer test system of claim 2, wherein the probe card further comprises at least one passive device or at least one active device connected to the at least one current limitation switch, wherein the test controller is configured to control the amplitude of the threshold current by adjusting a voltage or a current flowing in the at least one passive device or the at least one active device.

5. The wafer test system of claim 2, wherein the at least one current limitation switch receives power from an external power source.

6. The wafer test system of claim 2, wherein the at least one current limitation switch is configured to block the current flowing into the at least one DUT in response to the current flowing into the at least one DUT being greater than the threshold current for a predetermined amount of time.

7. The wafer system of claim 2, wherein the at least one current limitation switch is configured to reduce the current flowing into the at least one DUT to be about equal to or less than the threshold current in response to the current flowing into the at least one DUT being greater than the threshold current.

8. The wafer system of claim 1, wherein the amplitude of the threshold current varies according to the at least one DUT.

9. The wafer system of claim 1, wherein the test controller is configured to adjust the amplitude of the threshold current before testing the at least one DUT.

10. The wafer test system of claim 1, wherein the test controller is configured to adjust the amplitude of the threshold current while the at least one DUT is being tested.

11. A probe card, comprising:
a current limitation switch configured to control an amplitude of a current flowing into at least one device under test (DUT); and
a current limitation device configured to control an amplitude of a threshold current, wherein the current flowing into the at least one DUT flows through the current limitation device, the current limitation device is connected to the current limitation switch, and the current flowing through the current limitation device and into the at least one DUT is limited by the current limitation switch.

12. The probe card of claim 11, wherein the current limitation switch receives power from an external power source.

13. The probe card of claim 11, wherein the current limitation switch is configured to block the current flowing into the at least one DUT in response to the current flowing into the at least one DUT being greater than the threshold current for a predetermined amount of time.

14. The probe card of claim 11, wherein the current limitation switch is configured to reduce the current flowing into the at least one DUT to be about equal to or less than the threshold current in response to the current flowing into the at least one DUT being greater than the threshold current.

15. The probe card of claim 11, wherein the test controller is configured to adjust the amplitude of the threshold current while the at least one DUT is being tested.

16. A wafer test system, comprising:
a probe card connected to a plurality of devices under test (DUTs) disposed on a wafer, wherein the probe card is configured to limit a current flowing into each of the plurality of DUTs to be about equal to or less than a corresponding threshold current from among a plurality of threshold currents; and
a test controller configured to control an amplitude of each of the plurality of threshold currents.

17. The wafer test system of claim 16, wherein the probe card comprises a plurality of current limitation switches connected to the plurality of DUTs.

18. The wafer test system of claim 17, wherein the probe card further comprises a plurality of resistors connected to the plurality of current limitation switches, wherein the test controller is configured to control the amplitude of each of the plurality of threshold currents by adjusting resistance values of the plurality of resistors.

19. The wafer test system of claim 17, wherein the probe card further comprises a plurality of passive devices or a plurality of active devices connected to the plurality of current limitation switches, wherein the test controller is configured to control the amplitude of each of the plurality of threshold currents by adjusting voltages or currents flowing in the plurality of passive devices or the plurality of active devices.

20. The wafer test system of claim 17, wherein the plurality of current limitation switches receives power from an external power source.
